(19) United States
(12) Patent Application Publication
(10) Pub. No.: US 2017/0295668 A1
(43) Pub. Date: Oct. 12, 2017

(54) HEAT-DISSIPATION DEVICE AND ELECTRONIC APPARATUS

(71) Applicant: Lenovo (Beijing) Co., Ltd., Beijing (CN)

(72) Inventors: Zizhou JIA, Beijing (CN); Zhigang NA, Beijing (CN); Ying SUN, Beijing (CN)

(21) Appl. No.: 15/452,185

(22) Filed: Mar. 7, 2017

(30) Foreign Application Priority Data
Apr. 11, 2016 (CN) 201610222465.0

(51) Int. Cl. H05K 7/20; F28F 1/02

(52) U.S. Cl. CPC H05K 7/20145; F28F 1/022; H05K 7/20272; H05K 7/20263; F28F 2250/08

(57) ABSTRACT

A heat-dissipation device and an electronic apparatus are provided. The heat-dissipation device includes a pump and a pipe. The pump includes a rotary portion and a driving portion. The rotary portion is disposed in the pipe, and the driving portion is operative to provide a rotary driving force to the rotary portion to circulate a cooling fluid within the pipe.

### CROSS-REFERENCES TO RELATED APPLICATIONS

This application claims priority of Chinese Patent Application No. 201610222465.0, filed on Apr. 11, 2016, the entire content of which is hereby incorporated by reference.

### FIELD OF THE INVENTION

The present disclosure generally relates to the field of electronic technologies and, more particularly, relates to a heat-dissipation device and an electronic apparatus.

### BACKGROUND

With the development of electronic technologies, the size of the electronic apparatus becomes smaller and smaller, and the functions of the electronic apparatus become richer and richer. Often, the richer the functions of the electronic apparatus, the higher the power consumption, and the higher the generated heat. For ease of heat dissipation, a heat-dissipation device is often coupled to the electronic apparatus.

A heat-dissipation device often includes a pump and two pipes, and a fluid flows in the pipes to dissipate heat. Often, the pump includes an inlet and an outlet, and the inlet and the outlet are each connected to one of the pipes, respectively.

Because the inlet and the outlet of the pump connected to the pipes often incur fluid leakage or have high sealing requirements, the fabrication process of the inlet and the outlet may be relatively challenging, resulting in increased fabrication difficulty and cost.

The disclosed heat-dissipation device and electronic apparatus are directed to solving at least partial problems set forth above and other problems.

### BRIEF SUMMARY OF THE DISCLOSURE

One aspect of the present disclosure provides a heat-dissipation device. The heat-dissipation device includes a pump and a pipe. The pump includes a rotary portion and a driving portion. The rotary portion is disposed in the pipe, and the driving portion is operative to provide a rotary driving force to the rotary portion to circulate a cooling fluid within the pipe.

Another aspect of the present disclosure provides an electronic apparatus. The electronic apparatus includes a heat-generation component. A heat-dissipation device is coupled to the heat-generation component to dissipate heat generated by the heat-general on component during operation. The heat-dissipation device includes a pump and a pipe. The pump includes a rotary portion and a driving portion. The rotary portion is disposed in the pipe, and the driving portion is operative to provide a rotary driving force to the rotary portion to circulate a cooling fluid within the pipe.

Other aspects of the present disclosure can be understood by those skilled in the art in light of the description, the claims, and the drawings of the present disclosure.

### BRIEF DESCRIPTION OF THE DRAWINGS

In order to more clearly illustrate technical solutions in disclosed embodiments of the present invention, drawings necessary for the description of the disclosed embodiments are briefly introduced below. Obviously, the drawings described below are only some embodiments of the present invention, and it is possible for those ordinarily skilled in the art to derive other drawings from these drawings without creative effort.

FIG. 1 illustrates a top view of an external structure of an exemplary heat-dissipation device consistent with disclosed embodiments;

FIG. 2 illustrates a bottom view of an inner structure of an exemplary heat-dissipation device consistent with disclosed embodiments;

FIG. 3 illustrates a top view of an external structure of another exemplary heat-dissipation device consistent with disclosed embodiments;

FIG. 4 illustrates a side view of an external structure of an exemplary heat-dissipation device consistent with disclosed embodiments;

FIG. 5 illustrates a top view of an external structure of another exemplary heat-dissipation device consistent with disclosed embodiments;

FIG. 6 illustrates a side view of an inner structure of other exemplary heat-dissipation device consistent with disclosed embodiments;

FIG. 7 illustrates a bottom view of an inner structure of another exemplary heat-dissipation device consistent with disclosed embodiments; and

FIG. 8 illustrates a top view of an inner structure of an exemplary electronic apparatus consistent with disclosed embodiments.

### DETAILED DESCRIPTION

Reference will now be made in detail to exemplary embodiments of the invention, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are merely apart of, rather than entire, embodiments of the present invention. On the basis of the disclosed embodiments, other embodiments obtainable by those ordinarily skilled in the art without creative effort shall fall within the scope of the present invention.

The present disclosure provides an improved heat-dissipation device and electronic apparatus. According to the present disclosure, the heat-dissipation device includes a pump and a pipe, and the rotary portion of the pump is mounted inside the pipe. Accordingly, the number of connectors between the pump and the pipe is reduced, thus lowering the risk of the leakage phenomenon caused by failure in the sealing of the connectors. Further, the high difficulty in the fabrication process of the heat-dissipation device due to the high sealing requirements may be reduced.

### Embodiment 1

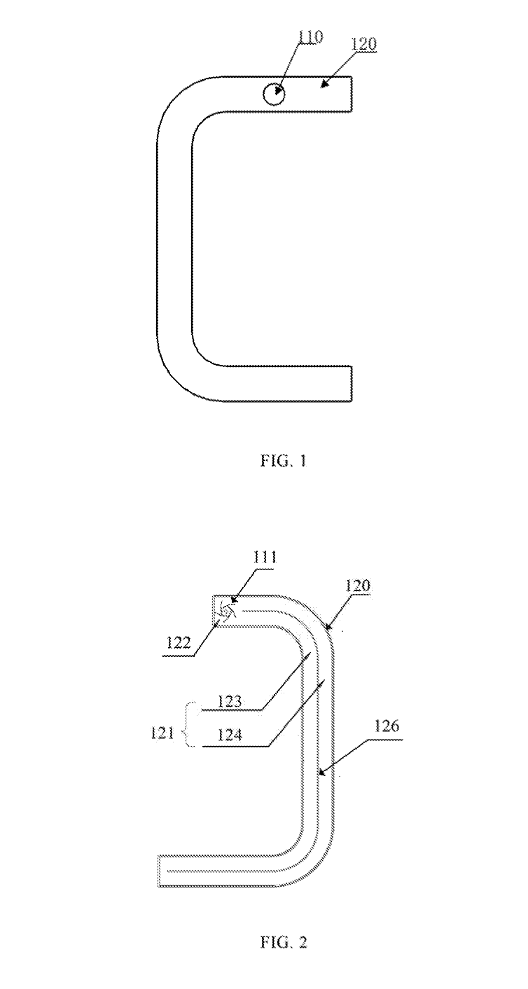

FIG. 1 illustrates a top view of an external structure of an exemplary heat-dissipation device consistent with disclosed embodiments. As shown in FIG. 1, the heat-dissipation device may include a pump 110 and a pipe 120. The pipe 120 may be designed into a “U” shape with rounded corners and two legs, and the two legs may be equal or may be different in length. Optionally, the pipe 120 may also be designed into an “L” shape or other shapes. The pump 110 may be located at an end of the pipe 120, or other regions of the pipe 120, such as the middle portion of the pipe 120.

FIG. 2 illustrates a bottom view of an inner structure of an exemplary heat-dissipation device consistent with disclosed embodiments. FIG. 4 illustrates a side view of an external structure of an exemplary heat-dissipation device consistent with disclosed embodiments. As shown in FIG. 2 and FIG. 4, the pump 110 may include a rotary portion 111 and a driving portion 112. The rotary portion 111 may be disposed inside the pipe 120. The driving portion 112 may be disposed outside of the pipe 120, and provide a rotary driving force to the rotary portion 111.

More specifically, the rotary portion 111 may include a plurality of blades, and the plurality of blades may be disposed around a rotation shaft. The rotation shaft may extend along an A-A direction (shown in FIG. 4), and the plurality of blades may each be disposed at an installable location circumferentially around the rotation shaft. Further, the plurality of blades may rotate when driven by the driving portion 112, and the driving portion 112 may include a unit that provides the rotary driving force. The unit may be, for example, an electric motor.

Referring to FIG. 2, the rotary portion 111 may include five blades disposed symmetrically around the rotation shaft. Optionally, the rotary portion 111 may include four blades, six blades, or seven blades, etc. Further, the number of the blades may be not equal to the number of the installable locations. Thus, the plurality of blades may be installed at every installable location, every other installable location, or have other symmetrical or asymmetric configurations.

The heat-dissipation device may use a fluid as a cooling medium, and the space inside the pipe 120 may be used as a space where the cooling medium flows. The fluid may specifically be a liquid, such as water, or a gas. Further, the heat-dissipation device may be coupled to an electronic apparatus to dissipate the heat generated by the electronic apparatus. In particular, the heat-dissipation device may often be disposed in contact with or adjacent to a heat-generation component (e.g., a CPU) of the electronic apparatus.

Because the rotary portion 111 is disposed inside the pipe 120, the rotary portion 111 may rotate and drive the fluid in the pipe 120 to flow. Further, by disposing the rotary portion 111 inside the pipe 120, a connector connecting the pump 110 to the pipe 120 may no longer be needed. Further, because the connector often includes at least an inlet and an outlet, the occurrence of fluid leakage caused by poor sealing of the connector between the pump 110 and the pipe 120 may be avoided. The fabrication process of the heat-dissipation device due to the high sealing requirements may also be simplified.

Specifically, the rotary portion 111 may be disposed inside the pipe 120 according to at least a plurality of situations as follows. In one situation, the whole pump 110, including the rotary portion 111 and the driving portion 112, may be disposed inside the pipe 120. The driving portion 112 may be disposed in the shell of the pump 110, and the rotary portion 111 may extend outside of the shell of the pump 110 into the pipe 120 via an opening of the pump 110. An energy source that supports the operation of the pump 110 may be electric energy stored in a battery, or electric energy supplied by a power transmission line that runs across the pipe 120. Thus, because the rotary portion 111 is also disposed in the pipe 120, the number of the connectors between the pump 110 and the pipe 120 may be reduced by at least one, which lowers the risk of fluid leakage at the connectors between the pipe 120 and the pump 110.

In another situation, the driving portion 112 of the pump 110 may be disposed outside of the pipe 120, and the rotary portion 111 may be disposed inside the pipe 120. The rotary portion 111 may be connected to the driving portion 112 via a rotation shaft, and the rotation shaft may be the same as the aforementioned rotation shaft that a plurality of blades is disposed around. Accordingly, only one connector may be needed between the pump 110 and the pipe 120, and the risk of the leakage phenomenon may be lowered.

In another situation, the driving portion 112 and the rotary portion 110 of the pump 110 may be separated, and the driving force between the driving portion 112 and the rotary portion 110 may be supplied by an electromagnetic field. Thus, no connector may be needed between the pump 110 and the pipe 120, thereby avoiding leakage caused by poor sealing of the connector.

Accordingly, the present disclosure provides a heat-dissipation device, the rotary portion of the pump in the heat-dissipation device may be disposed inside the pipe that accommodates the fluid flow. Thus, the risk of leakage phenomenon at the connectors between the pipe and the pump may be lowered, and the high difficulty in the fabrication process of the heat-dissipation device due to the high sealing requirements may be reduced.

### Embodiment 2

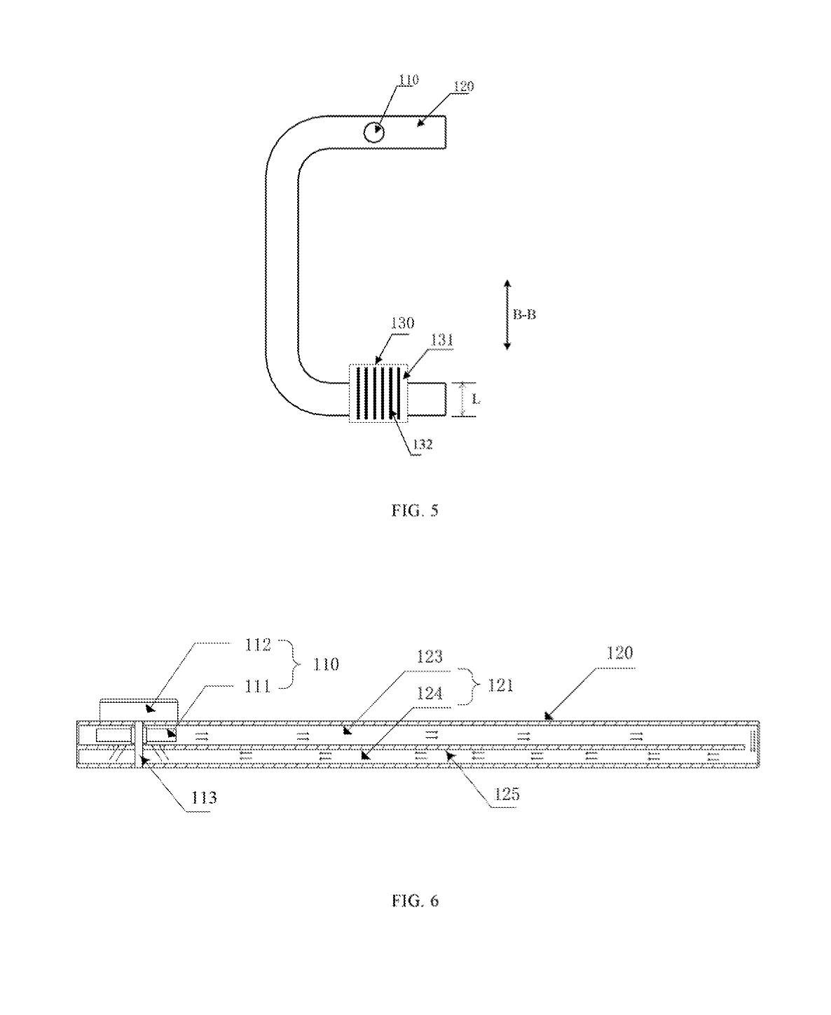

FIG. 5 illustrates a top view of an external structure of another exemplary heat-dissipation device consistent with disclosed embodiments. As shown in FIG. 5, the heat-dissipation device may include a pump 110, a pipe 120, and a heat-dissipation structure 130. Referring to FIG. 2 and FIG. 4, the pump 110 may include a rotary portion 111 and a driving portion 112. The rotary portion 111 may be disposed in the pipe 120, and the driving portion 112 may provide a rotary driving force to the rotary portion 111.

Further, referring to FIG. 5, the pipe 120 may be designed into a “U” shape with rounded corners and two legs. The two legs of the pipe 120 may be equal or may be different in length. The heat-dissipation structure 130 may be connected to the pipe 120, and utilize the fluid in the pipe 120 to dissipate heat.

Specifically, the heat-dissipation structure 130 may include a heat-dissipation plate 131, and a passage for the fluid to flow through, etc. The heat-dissipation plate 131 may be made of a heat-dissipation material (e.g., a metal) with a thermal conductivity higher than a designated value. The passage may be, for example, defined by a plurality of cooling tubes 132 arranged in parallel to each other as shown in FIG. 5. Further, the passage may include two ends (not shown), and the two ends may each be connected to an end of the pipe 120, respectively, thus forming a fluid circulation passage for heat dissipation.

Optionally, a plurality of passages may be configured in the heat-dissipation structure 130. The heat-dissipation structure 130 may include an inlet and an outlet, and the plurality of passages may be specifically configured between the inlet and the outlet. For example, an N number of passages may be configured between the inlet and the outlet, where N is an integer greater than 1. Further, the inlet and the outlet may each be connected to an end of the pipe 120, respectively, thus forming a fluid circulation passage for heat dissipation.

Because the heat-dissipation structure 130 may only include one pipe 120, the number of the passages configured in the heat-dissipation structure 130 may be greater than the number of the pipes 120. Further, the passages may be configured in various locations throughout the heat-dissipation structure 130, thus enabling the heat-dissipation structure 130 to rapidly and uniformly absorb heat from the fluid flowing in the plurality of passages, and dissipate heat outwards.

Optionally, the heat-dissipation structure 130 may be integrated with the pipe 120. The heat-dissipation structure 130 may include a plurality of heat-dissipation plates 131. The plurality of heat-dissipation plates 131 may function as walls of the pipe 120, thus further reducing the number of the connectors. Accordingly, the sealing may be improved, the risk of leakage phenomenon may be lowered, and the difficult of the fabrication process may be reduced.

When the heat-dissipation structure 130 is integrated with the pipe 120, the width of the heat-dissipation structure 130 in a direction (i.e., a B-B direction in FIG. 5) perpendicular to the fluid flow direction may be greater than the dimension L of the pipe 120 along the same direction. Accordingly, the heat-dissipation area may be increased, thereby dissipating heat quickly and improving the heat-dissipation efficiency.

### Embodiment 3

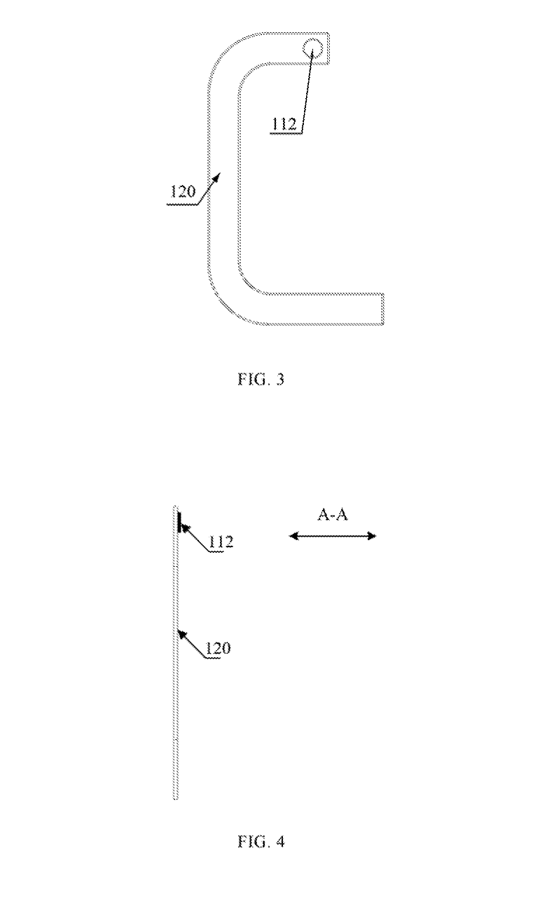

FIG. 3 illustrates a top view of an external structure of another exemplary heat-dissipation device consistent with disclosed embodiments. FIG. 6 illustrates a side view of an inner structure of another exemplary heat-dissipation device consistent with disclosed embodiments. As shown in FIG. 3 and FIG. 6, the heat-dissipation device may include a pump 110 and a pipe 120.

The pump 110 may include a rotary portion 111 and a driving portion 112. The rotary portion 111 may be disposed in the pipe 120. The driving portion 112 may be disposed outside of the pipe 120, and provide a rotary driving force to the rotary portion 111. The rotary portion 111 may be connected to the driving portion 112 via a rotation shaft 113.

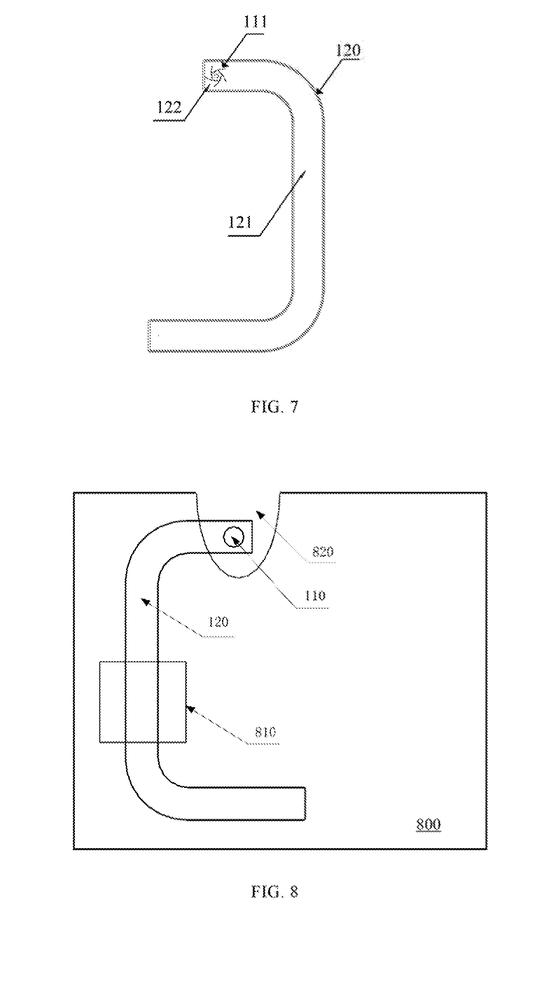

FIG. 7 illustrates a bottom view of an inner structure of another exemplary heat-dissipation device consistent with disclosed embodiments. Referring to FIG. 6 and FIG. 7, the pipe 120 may include an isolation region 121 and a non-isolation region 122.

The rotary portion 111 may be disposed in the non-isolation region 122. An isolation layer 125 may be disposed in the isolation region 121 and divide the isolation region 121 into a first channel 123 and a second channel 124 on different layers. The pump 110 may drive the fluid to flow circularly in the first channel 123, the second channel 124, and the non-isolation region 122. The direction of the fluid flow may be, for example, indicated by a plurality of paired arrows shown in FIG. 6.

Optionally, referring to FIG. 2, the isolation region 121 and the non-isolation region 122 may be configured on the sane layer. More specifically, an isolation wall 126 may be disposed in the isolation region 121 and divide the isolation region 121 into the first channel 123 and the second channel 124 on the same layer. Similarly, the pump 110 may drive the fluid to flow circularly in the first channel 123, the second channel 124, and the non-isolation region 122.

By disposing the isolation layer 125 or the isolation wall 126, the isolation region 121 of the pipe 120 may be divided into two sub-regions, such that two relatively isolated channels may be formed in the pipe 120. The two relatively isolated channels may be the first channel 123 and the second channel 124, respectively. In particular, the first channel 123 and the second channel 124 may be connected in the non-isolation region 122, thereby forming a circular flow path of the fluid.

More specifically, the first channel 123 and the second channel 124 may be configured in locations corresponding to the isolation layer 125 or the isolation wall 126. That is, the first channel 123 and the second channel 124 may not be connected in areas where the isolation layer 125 or the isolation wall 126 is disposed.

Further, by disposing the rotary portion 111 in the non-isolation region 122, the rotary portion 111 may pump the fluid from the first channel 123 into the second channel 124, or pump the fluid from the second channel 124 into the first channel 123, thereby enabling the circular flow of the fluid in the pipe 120.

Optionally, more than two channels may be configured in the pipe 120. The non-isolation region, where the rotary portion 111 is disposed may be a region that connects the at least two channels, thereby forming a circular flow path of the fluid in the pipe 120.

Further, because the pipe 120 is divided into the first channel 123 and the second channel 124 that share the same isolation layer 125 or the same isolation wall 126 as a channel wall, the length of the pipe 120 may be reduced, and the volume occupied by the walls of the pipe 120 may be reduced. Accordingly, the size of the heat-dissipation device may be decreased, which allows the heat-dissipation device to be conveniently applied to an electronic apparatus, resulting in thin and light-weighted electronic apparatus.

Optionally, the heat-dissipation device may further include a heat-dissipation structure 130, or other structures designed for heat dissipation. However, the present disclosure is not limited thereto. For example, in specific implementation, the heat-dissipation device may include no heat-dissipation structure. Specifically, the pipe may be fabricated using a material with good thermal conductivity, and a part of the pipe may be disposed in a non-heat generation portion or a ventilation portion of the electronic apparatus. Thus, when the fluid flows in the pipe, heat exchange may occur between the pipe and the external environment, resulting in a heat dissipation effect.

### Embodiment 4

Referring to FIG. 1, the present disclosure provides a heat-dissipation device. The heat-dissipation device may include a pump 110 and a pipe 120. The pump 110 may include a rotary portion 111 and a driving portion 112. The rotary portion 111 may be disposed in the pipe 120, and the driving portion 112 may provide the rotary driving force to the rotary portion.

Further, referring to FIG. 6 and FIG. 7, the pipe 120 may include an isolation region 121 and a non-isolation region 122. The rotary portion 111 may be disposed in the non-isolation region 122, and an isolation layer 125 may be disposed in the isolation region 121. The isolation layer 125 may divide the pipe 120 into a first channel 123 and a second channel 124. The pump 110 may drive the fluid to flow circularly in the first channel 123, the second channel 124, and the non-isolation region 122.

Further, the non-isolation region 122 may include a first non-isolation region and a second non-isolation region. The first non-isolation region and the second non-isolation region may be disposed at two ends of the pipe 120, respectively. In particular, the rotary portion 111 may be disposed in the first non-isolation region.

The pipe 120 may be a stripe-shaped pipe. The stripe-shaped pipe may be a straight stripe-shaped pipe or an arc-like stripe-shaped pipe. However, the present disclosure is not intended to limit the shape of the pipe 120 as long as the pipe 120 includes two separated ends. Further, because the non-isolation region 122 includes two non-isolation regions (e.g., the first non-isolation region and the second non-isolation region) disposed at two ends of the pipe 120, respectively, the length of the fluid flow path may be maximized.

Accordingly, the fluid may, for example, flow from the first channel 123 of the pipe 120 into the second channel 124 via the first non-isolation region, and flow fro the second channel 124 back to the first channel 123 via the second non-isolation region. Optionally, in specific implementation, because the first non-isolation region and the second non-isolation region are disposed at two ends of the pipe 120, respectively, the fluid may also flow from the first channel 123 into the second channel 124 via the second non-isolation region, and flow from the second channel 124 back to the first channel 123 via the first non-isolation region. Optionally, the first non-isolation region and the second non-isolation region may also be disposed at other locations in addition to the two ends of the pipe 120.

Further, by disposing the rotary portion 111 in the first non-isolation region, the pump 110 may enhance the fluid flow by rotating the rotary portion 111 in the first non-isolation region. The first non-isolation region and the second non-isolation region may not refer to particular non-isolation regions, but are merely used to differentiate the two non-isolation regions.

In specific implementation, the non-isolation region 122 may include two or more non-isolation regions. For example, the non-isolation region 122 may include three non-isolation regions. Among the three non-isolation regions, two non-isolation regions (i.e., the first non-isolation region and the second non-isolation region) may be configured at the two ends of the pipe 120, and a third non-isolation region may be configured in the middle of the pipe 120.

Further, the rotary portion 111 may be disposed in the third non-isolation region in the middle of the pipe 120. Thus, the rotary portion 111 may form two or more fluid circulation passages in the pipe 120 via self-rotation, and heat exchange may be realized. However, the fluid circulation passages formed by disposing the rotary portion 111 in the middle of the pipe 120 may not be common circulation passages.

Further, the heat-dissipation device may also include a structure specifically designed for heat dissipation. For example, the heat-dissipation device may include the heat-dissipation structure 130 as shown in FIG. 5.

### Embodiment 5

Referring to FIG. 1, the present disclosure provides a heat-dissipation device. The heat-dissipation device may include a pump 110 and a pipe 120. Referring to FIG. 2 and FIG. 4, the pomp 110 may include a rotary portion 111 and a driving portion 112. In particular, the rotary portion 111 may be disposed in the pipe 120, and the driving portion 112 may provide a rotary driving force to the rotary portion 111.

The pipe 120 may it an isolation region 121 and a non-isolation region 122. The rotary portion 111 may be disposed in the non-isolation region 122. An isolation wall 126 may be disposed in the isolation region 121, and the isolation wall 126 may divide the pipe 120 into a first channel 123 and a second channel 124.

Further, the pump 110 may drive the fluid to circulate in the first channel 123, the second channel 124, and the non-isolation region 122. The non-isolation region 122 may further include a first non-isolation region and a second non-isolation region. The first non-isolation region and the second non-isolation region may be disposed at two ends of the pipe 120.

More specifically, the isolation wall 126 may divide the pipe 120 into the first channel 123 and the second channel 124 along a first direction the A-A direction in FIG. 4). The first direction may be a direction perpendicular to a rotary plane of the rotary portion 111.

By disposing the rotary plane of the rotary portion 111 perpendicular to the extension direction the first direction) of the isolation wall 126, the rotary driving three that drives the rotary portion 111 to rotate may be maximally converted to a driving force that drives the fluid flow. Accordingly, the working efficiency of the pump 110 may be improved.

For example, if the rotary portion 111 rotates in a horizontal plane, the isolation layer may be disposed in a direction perpendicular to the horizontal plane. That is, the isolation layer may be perpendicular to the rotary plane. Thus, the rotary portion 111 may enhance the fluid flow in the first channel 123 and the second channel 124, and improve the effective power of the pump 110.

Further, the heat-dissipation device may also include a structure specifically designed for heat dissipation. For example, the heat-dissipation device may include the heat-dissipation structure 130 as described in FIG. 5. Further, the non-isolation region 122 of the disclosed heat-dissipation device may also include at least two non-isolation regions at two ends of the pipe 120.

### Embodiment 6

Referring to FIG. 1, the present disclosure provides a heat-dissipation device. The heat-dissipation device may include a pump 110 and a pipe 120. The pump 110 may include a rotary portion 111 and a driving portion 112. In particular, the rotary portion 111 may be disposed in the pipe 120, and the driving portion 112 may provide a rotary driving force to the rotary portion 111. The pipe 120 may be a flat metal pipe. The fiat metal pipe may have a rectangular cross-sectional shape.

Specifically, the pipe 120 may be a metal pipe. The metal pipe may refer to a pipe made of a single metal, or a pipe made of a metallic alloy or metallic oxide. Further, the cross-sectional shape of the metal pipe may be rectangular or any other flat geometric shape. The metal pipe with a rectangular cross-sectional shape may show features such as a regular shape and an easy fabrication process.

Further, the flat pipe 120 with a rectangular cross-sectional shape may be disposed in an electronic apparatus including a plurality of components in regular shapes (e.g., rectangular, square, etc.). Thus, the phenomenon that the pipe 120 cannot be well assembled with other electronic components in an electronic apparatus due to the irregular shape of the pipe 120 may be avoided. Accordingly, the electronic apparatus may be fabricated to be relatively small.

Further, the heat-dissipation device may also include a specific heat-dissipation structure. Or, the pipe 120 may be multiplexed as the heat-dissipation structure to exchange heat with the external environment.

### Embodiment 7

Referring to FIG. 1, the present disclosure provides a heat-dissipation device. The heat-dissipation device may include a pump 110 and a pipe 120. The pump 110 may include a rotary portion 111 and a driving portion 112. In particular, the rotary portion 111 may be disposed in the pipe 120, and include a first magnetic component. The driving portion 112 may be located outside of the pipe 120 and provide a rotary driving force to the rotary portion 111. Specifically, the driving portion 112 may drive the first magnetic component to rotate via a magnetic force (also named magnetic field force).

The first magnetic component may be impellers or blades, etc., of the rotary portion 112. Further, the first magnetic component may be made of iron or other magnetic materials. The first magnetic component may rotate under the effect of the magnetic force. Accordingly, the driving portion 112 may drive the first magnetic component to rotate by providing the magnetic force, and the driving portion 112 and the rotary portion 111 may be separately disposed.

Optionally, the driving portion 112 may be disposed outside of the pipe 120, and the magnetic force provided by the driving portion 112 may drive the first magnetic component to rotate in a wireless manner. Thus, only the rotary portion 111 may need to be disposed in the pipe 120, and no connector may be needed between the driving portion 112 and the pipe 120. Accordingly, the sealing of the heat-dissipation device my be maximally improved, and the risk of fluid leakage may be reduced.

### Embodiment 8

Referring to FIG. 1, the present disclosure provides a heat-dissipation device. The heat-dissipation device may include a pump 110 and a pipe 120. The pump 110 may include a rotary portion 111 and a driving portion 112. In particular, the rotary portion 111 may be disposed in the pipe 120 and include a first magnetic component. The driving portion 112 may be located outside of the pipe 120 and provide a rotary driving force to the rotary portion 111. Specifically, the driving portion 112 may drive the first magnetic component to rotate via a magnetic force (also named magnetic field force).

Further, the driving portion 112 may include a second magnetic component. The driving portion 112 may drive the first magnetic component to rotate by driving the second magnetic component to rotate. The second magnetic component may, for example, be an electromagnet, and the electromagnet itself may supply a magnetic force to other magnetic components. For example, the electromagnet may provide a magnetic three that attracts the iron.

Optionally, the first magnetic component may be a component, such as iron, that cannot form a magnetic force by itself. The second magnetic component may be a magnetic component, such as a lodestone. The driving portion 112 may drive the second magnetic component to rotate, and a rotation radius of the driving portion 112 may be a first radius. The rotation radius of the second magnetic component may be a second radius. Due to the rotation of the second magnetic component, the relative positions between the first magnetic component and the second magnetic component may vary. Under the effect of the magnetic force, the first magnetic component may rotate as the second magnetic component rotates.

For example, the rotary portion 111 may include three blades, and one of the three blades may be a blade that moves towards the second magnetic component under the effect of the magnetic force supplied by the second magnetic component. If the second magnetic component rotates, the one of the three blades may be attracted to rotate, and other blades in the first magnetic component may rotate correspondingly, thus realizing the driving of the second magnetic component.

Optionally, the first magnetic component and the second magnetic component may both be components that produce a magnetic force. The magnetic force may be an attractive force or a repulsive force. By rotating the second magnetic component, the interactive force between the second magnetic component and the first magnetic component may be varied, thus driving the first magnetic component to rotate.

Accordingly, the present disclosure provides a heat-dissipation device including a pump and a pipe. The pump may include a rotary portion 111 and a driving portion 112. The rotary portion 111 and the driving portion 112 may be separately disposed. Further, the rotary portion 111 and the driving portion 112 may interact with each other via a magnetic force. Thus, the driving of the rotary portion 111 may be realized, and the heat-dissipation device may show features such as having a simple structure and good sealing.

### Embodiment 9

Referring to FIG. 1, the present disclosure provides a heat-dissipation device. The heat-dissipation device may include a pump 110 and a pipe 120. The pump 110 may include a rotary portion 111 and a driving portion 112. In particular, the rotary portion 111 may be disposed in the pipe 120 and include a first magnetic component. The driving portion 112 may be located outside of the pipe 120 and provide a rotary driving force to the rotary portion 111. Specifically, the driving portion 112 may drive the first magnetic component to rotate via a magnetic force (also named a magnetic field force).

The driving portion 112 may form a variable electromagnetic field in a location where the first magnetic component is disposed. Via the variable electromagnetic field, the driving portion 112 may drive the first magnetic component to rotate.

Specifically, the driving portion 112 may include an electromagnetic-generating component, thus forming a variable electromagnetic field. Accordingly, in response to the variation of the electromagnetic field, the force applied on the first magnetic component may vary. Thus, the variable electromagnetic field may drive the first magnetic component to rotate, thereby enabling the driving portion 112 and the rotary portion 111 to be disposed separately. Accordingly, the sealing of the heat-dissipation device may be improved.

For example, the driving portion 112 may include three groups of coils that produce an electromagnetic field. Each group of coils may be disposed on two sides of the central line of the driving portion 112 corresponding to the rotary center of the rotary portion 111. Each group of coils may produce an electromagnetic field that attracts the first magnetic component. Further, because the groups of coils may produce an electromagnetic field that varies periodically, the electromagnetic field may be varied, thus enabling the first magnetic component to rotate.

However, the present disclosure is not intended to limit the specific structure of the electromagnetic-generating component as long as the driving portion 112 produces an electromagnetic field. For example, the driving portion 112 may include four groups of coils.

### Embodiment 10

The present disclosure also provides an electronic apparatus. FIG. 8 illustrates a top view of an inner structure of an exemplary electronic apparatus consistent with disclosed embodiments. As shown in FIG. 8, the electronic apparatus 800 may include a heat-generation component 810, a ventilation portion 820, and a heat-dissipation device (not labeled), etc. The heat-dissipation device may include a pump 110 and a pipe 120.

Specifically, the heat-generation component 810 may be disposed in contact with or adjacent to the heat-dissipation device. For example, the heat-generation component 810 may be disposed in contact with or adjacent to the pipe 120. The ventilation portion 820 may correspond to another part of the pipe 120, and the pump 110 may drive a fluid to flow in the pipe 120, thus allowing heat exchange between the pipe 120 and the external environment.

Further, the heat-dissipation device may also include a heat-dissipation structure 130 as shown in FIG. 5. The heat-generation component 810 may then be disposed in contact with or adjacent to the heat-dissipation structure 130. Optionally, the heat-dissipation device may be any aforementioned heat-dissipation device, and the present disclosure is not intended to be limiting.

Further, the electronic apparatus 800 may be an apparatus that needs to dissipate heat, such as a laptop computer, a tablet computer, a desktop computer or a TV station. The heat-generation portion 810 may be, for example, a central processor unit (CPU) or a graphic processor unit (GPU), etc.

Because the electronic apparatus adopts the heat-dissipation device that shows good fluid sealing, a failure of the electronic apparatus caused by leakage of the fluid (particularly the liquid) in the heat-dissipation device may be avoided. Further, because the heat-dissipation device shows features such as a simple fabrication process and a low fabrication cost, the fabrication the electronic apparatus may also be relatively simple, resulting in a low cost.

In various embodiments of the present disclosure, it should be understood that, the disclosed device and method may be implemented by other manners. The device described above is merely for illustrative purpose. For example, the units may be merely partitioned by logic function. In practice, other partition manners may also be possible. For example, various units or components may be combined or integrated into another system, or some features may be omitted or left unexecuted. In addition, mutual coupling, direct coupling, or communication displayed or discussed herein may be indirect coupling or communication connection in electrical, mechanical, or other forms through some interfaces, apparatus, or units.

Units described as separated components may or may not be physically separated, and the components serving as display units may or may not be physical units. That is, the components may be located at one position or may be distributed over various network units. Optionally, some or of the units may be selected to realize the purpose of solutions of embodiments herein according to practical needs.

Further, the various functional units of various embodiments of the invention may be integrated into one processing unit, or may present individually. Two or more units may be integrated into one unit. The integrated unit may be realized in a hardware form, or in a form combining the hardware and software functional units.

Those ordinarily skilled in the art may understand that all or a part of the steps of the above embodiments may be realized via hardware relevant to the program demands, and previous programs may be stored in computer readable storage media. When the program is being executed, the steps of the above embodiments may be executed. The storage media described above may include portable storage device, Read-Only Memory (ROM), Random Access Memory (RAM), a magnetic disc, an optical disc or any other media that may store program codes.

The disclosed embodiments described above are merely exemplary embodiments of the present disclose, but the protection scope of the present disclosure is not limited thereto. Any modification or substitution readily conceivable by those skilled in the art within the scope of the technology disclosed herein shall within the scope of the present invention, which is subjected to the appended claims.

What is claimed is:

1. A heat-dissipation device, comprising:
a pipe; and
a pump coupled to the pipe, the pump including a rotary portion and a driving portion,
wherein the rotary portion is disposed in the pipe and the driving portion is operative to provide a rotary driving force to the rotary portion to circulate a cooling fluid within the pipe.

2. The device according to claim 1, further comprising:
a heat-dissipation structure connected to the pipe and utilizing the fluid in the pipe to dissipate heat.

3. The device according to claim 1, wherein:
the pipe includes an isolation region and a non-isolation region;
the rotary portion is disposed in the non-isolation region;
an isolation layer is disposed in the isolation region and divides the pipe into a first channel and a second channel; and
the pump drives the fluid to flow circularly in the first channel, the second channel, and the non-isolation region.

4. The device according to claim 3, wherein:
the non-isolation region includes a first non-isolation region and a second non-isolation region;
the first non-isolation region and the second non-isolation region are located at two ends of the pipe; and
the rotary portion is disposed in the first non-isolation region.

5. The device according to claim 3, wherein:
the isolation layer divides the channel into the first channel and the second channel along a first direction; and
the first direction is perpendicular to a rotary plane of the rotary portion.

6. The device according to claim 1, wherein:
the channel is a flat metal pipe; and
a cross-sectional shape of the metal pipe is rectangular.

7. The device according to claim 1, wherein:
the rotary portion includes a first magnetic component; and
the driving portion is located outside of the pipe and drives the first magnetic component to rotate via a magnetic force.

8. The device according to claim 7, wherein:
the driving portion includes a second magnetic component; and
the driving portion drives the second magnetic component to rotate by driving the first magnetic component to rotate.

9. The device according to claim 7, wherein:
the driving portion forms a variable electromagnetic field in a location where the first magnetic component is disposed, and drives the first magnetic component to rotate via the variable electromagnetic field.

10. An electronic apparatus, comprising:
a heat-generation component; and
a heat-dissipation device coupled to the heat-generation component to dissipate heat generated by the heat-generation component, wherein the heat-dissipation device comprises:
a pump including
a pipe; and
a rotary portion and a driving portion, wherein the rotary portion is disposed in the pipe and the driving portion is operative to provide a rotary driving force to the rotary portion to circulate a cooling fluid within the pipe.

11. The apparatus according to claim 10, wherein the heat-dissipation device further comprises:
a heat-dissipation structure connected to the pipe and utilizing the fluid in the pipe to dissipate heat.

12. The apparatus according to claim 10, wherein:
the pipe includes an isolation region and a non-isolation region;
the rotary portion is disposed in the non-isolation region;
an isolation layer is disposed in the isolation region and divides the pipe into a first channel and a second channel; and
the pump drives the fluid to flow circularly in the first channel, the second channel, and the non-isolation region.

13. The apparatus according to claim 12, wherein:
the non-isolation region includes a first non-isolation region and a second non-isolation region;
the first non-isolation region and the second non-isolation region are located at two ends of the pipe; and
the rotary portion is disposed in the first non-isolation region.

14. The apparatus according to claim 12, wherein:
the isolation layer divides the channel into the first channel and the second channel along a first direction; and
the first direction is perpendicular to a rotary plane of the rotary portion.

15. The apparatus according to claim 10, wherein:
the channel is a flat metal pipe; and
a cross-sectional shape of the metal pipe is rectangular.
